(19) United States
(12) Patent Application Publication
(10) Pub. No.: US 2012/0055527 A1
(43) Pub. Date: Mar. 8, 2012

(54) STRUCTURAL ELEMENT FOR THERMALLY SHIELDING ENGINES OR ENGINE COMPONENTS, IN PARTICULAR A HEAT SHIELD FOR COMBUSTION ENGINES

(75) Inventor: Beate Zika-Beyerlein, Nurnberg (DE)

(73) Assignee: ELRINGKLINGER AG, Dettingen-Erms (DE)

(21) Appl. No.: 13/254,722

(22) PCT Filed: Feb. 26, 2010
(86) PCT No.: PCT/EP2010/001206

§ 371 Date: Nov. 15, 2011

(30) Foreign Application Priority Data
Mar. 4, 2009 (DE) 102009012841.7
Feb. 26, 2010 (EP) PCT/EP2010/001206

(51) Int. Cl. H01L 35/32

(52) U.S. Cl. 136/205

(57) ABSTRACT

The invention relates to a structural element for thermally shielding engines or engine components, in particular a heat shield for combustion engines, the structural element having a planar extension and comprising a first side that faces a hot element of the engine, and a second side that faces away from the hot element of the engine, characterized in that the structural element comprises a thermoelectric generator, which can be used to generate electric energy from a temperature difference resulting between the first side and the second side of the structural element during operation of the engine.

### FIELD OF THE INVENTION

The invention relates to a structural element for thermally shielding engines or engine components, in particular a heat shield for combustion engines; the structural element has a flat expanse and has a first side that is oriented toward the hot engine component and a second side that is oriented away from the hot engine component.

### BACKGROUND OF THE INVENTION

Carrying out thermal management, for example in motor vehicles, and meeting requirements for thermal and acoustic shielding systems involves complex challenges because modern engines are distinguished by ever greater power densities while having ever smaller amounts of space available to them. The amount of available space is dictated by factors such as vehicle design, air resistance, and the presence of passenger safety systems. At the same time, an increasing number of components must be taken into account, for example due to stricter emissions requirements, the greater number of electronic components for controlling the engine and auxiliary systems, and last but not least, the comfort expectations of the end customer. The limited amount of space available hinders the circulation of cooling air required to dissipate heat. A majority of components must therefore be protected from excessive temperatures.

The primary function of shielding elements is to protect temperature-sensitive components. Heat sources in the vehicle include, for example, the exhaust-conveying parts such as the exhaust pipe, turbochargers, catalytic converters, soot particle combustion systems, and the like. Predominantly, the shielding elements or heat shields are three-dimensional free-form surface components that can also be referred to as structural elements. The shielding element should be placed as close as possible to the heat source in order to protect the surroundings from the thermal energies generated during operation, whether by means of radiation or convection. The known heat shields provide a thermal shield; at the same time as the thermal shielding, however, they can also provide a noise damping.

DE 10 2007 005 520 A1 has disclosed a vehicle with a thermoelectric generator that is equipped with a heat-absorbing element thermally coupled to the heat-emitting component and generates electrical energy from the temperature difference between the heat-absorbing element and a heat sink. The thermoelectric generator in this case is situated directly against the heat-emitting component and is connected to it in a thermally conductive way.

DE 10 2007 035 931 A1 has disclosed a device for a thermoelectric generator composed of a base plate on the high-temperature side and a base plate on the low-temperature side, with a semiconductor matrix situated between the base plates; the base plate on the low-temperature side and the base plate on the high-temperature side have an essentially two-dimensional shape; the base plate on the high-temperature side can be integrally joined to a hot surface and/or the base plate on the low-temperature side can be integrally joined to a cold surface.

The object of the invention is to create a structural element, in particular a heat shield, for engines, which has an expanded range of functions. In one embodiment of the invention, the shielded heat should be used for energy recovery.

### SUMMARY OF THE INVENTION

In one embodiment, the structural element has a thermoelectric generator that is able to generate electrical energy from a temperature difference that arises between the first side and the second side of the structural element during operation of the engine. Preferably, it is possible to generate the electrical energy directly from the temperature difference and in particular, without moving or rotating parts. The thermoelectric generator can be situated between the first side and the second side of the structural element, in particular it can be connected in a directly heat-conducting fashion to the first side on the one hand and to the second side on the other. For example, the so-called Seebeck effect can be used for the energy conversion, according to which charge carriers diffuse their energy from a hot end to a cold end of a conductor or semiconductor. The combination of different materials or differently doped materials, in particular, differently doped semiconductor materials, permits a voltage to be tapped at the free ends of a conductor pair that are connected to each other, the power of which voltage depends on the temperature difference. Possible materials for the thermoelectric generator include bismuth telluride (Bi₂Te₃), lead telluride (PbTe), or silicon germanium (SiGe), for example, and also any currently known materials or materials to be developed in future that have a sufficient thermoelectric power.

It is advantageous to provide good thermal coupling of the hot and cold sides of the thermoelectric generator to the corresponding first and second sides of the structural element. If aluminum is used as the material for the structural element, in particular individual aluminum layers, then the structural element can be formed onto the thermoelectric generator or the thermoelectric generator can be mounted so that it contacts the whole area of the corresponding side of the structural element. The structural element can be composed of sheet metal, in particular sheet aluminum, with a thickness of less than 1 mm or can be composed of a plurality of sheet metal layers and can be adapted to the contour of the thermoelectric generator. If necessary, an electrically insulating layer can be mounted on the associated contact surface of the thermoelectric generator and/or the contact surface of the structural element and can be composed, for example, of aluminum oxide when aluminum is used as the material for the structural element. The structural component can also be anodized on at least part of its surface, preferably all of it.

In one embodiment, the thermoelectric generator has a first section and a second section that each have a first end and a second end. The two sections can be manufactured out of different materials or combinations of materials and/or can be differently doped. When semiconducting materials are used, the two sections can be doped differently from each other, i.e. can be intentionally contaminated with foreign atoms in different ways, in particular foreign atoms that are incorporated into crystal lattice positions. Both sections can be manufactured of the same material, with one section being n-doped and the other section being p-doped.

The first ends of the two sections can be electrically connected to each other and can be connected in a thermally conductive fashion to one of the two sides of the structural element, for example to the first side that is oriented toward the hot engine component. The first ends of the two sections can also be electrically connected directly through the structural element itself. The two ends of the two sections can be connected in a thermally conductive fashion to the other of the two sides of the structural element, in particular to the second side of the structural element that is oriented away from the hot engine component. When there is a temperature difference between the two sides of the structural element, then an electrical voltage is present between the two ends of the two sections.

The energy generated by the theoretical generator can be fed into the electrical system for example of a motor vehicle; this electrical energy can either be used directly to drive electrical consumers of the vehicle or can be fed into the electrochemical energy storage unit generally provided in a motor vehicle. In both cases, a considerable reduction in the fuel consumption of the engine is achieved. It is advantageous that the structural element according to the invention is capable, over a relatively large area, of absorbing the thermal output of the engine—which was previously dissipated to the environment and therefore lost—and converting it into electrical energy. The increasing tendency to develop fully encapsulated motors has an advantageous effect on the amount of electrical energy that can be generated.

In one embodiment, the thermoelectric generator has sections that are spaced apart from each other, for example thermoelectric arms; the region between the sections can be at least partially filled with a thermal insulation material. In the simplest case, this can be a gas. The use of a foam or a silicone offers the advantage of reliably preventing the penetration of moisture into the thermoelectric generator. This moisture results in a basically undesirable increase in the thermal conductivity between the cold side and hot side of the thermoelectric generator and on the other hand, the moisture can also cause likewise undesirable corrosion. Preferably, the insulation material entirely covers the sections of the thermoelectric generator.

In one embodiment, the structural element is multilayered, having a first layer constituting the first side of the structural element and a second layer constituting its second side. The thermoelectric generator can be situated between the two layers and can be connected to the two layers in a thermally conductive fashion. The first and/or second layer can be composed of foil or sheet metal. A hot side of the thermoelectric generator can be in contact with a first surface of the first layer. A second surface of the first layer opposite from the first surface can be oriented toward the hot engine component. A first surface of the second side can be in contact with a cold side of the thermoelectric generator. A second surface of the second layer opposite from the first surface can be oriented away from the hot engine component. The structural element can also have a plurality of layers and a plurality of thermoelectric generators can be situated next to one another between two layers or be arranged one after another in cascade form.

In one embodiment, the two layers of the structural element overlap the thermoelectric generator. The two layers can be thermally insulated from each other in a region adjacent to the thermoelectric generator. In particular, the two layers can be spaced apart from each other by a thermal insulation material in a region adjacent to the thermoelectric generator. The insulation material can also function as a spacer and can also possibly serve to absorb compressive forces and prevent them from acting on the thermoelectric generator. The insulation material can be composed of a cured plastic or cured foam.

In one embodiment, the electrical connecting lines of the thermoelectric generator are routed through at least two layers of the structural element. The connecting lines can be embodied in the form of wire lines, sheet metal lines, or conductor tracks that are applied to the layers. In any case, their placement between the layers of the structural element protects the connecting lines from being damaged by mechanical or thermal influences.

In one embodiment, at least one of the two layers of the structural element, on its side oriented toward the thermoelectric generator, has a connecting electrode for electrically contacting the thermoelectric generator and/or has electric conductor tracks. In particular, the connecting electrodes or conductor tracks can be applied directly to the layers of the structural element, e.g. with the thin-film or thick-film technique, vapor depositing, or some other method. This makes it easy to produce a connection between the connecting electrodes without requiring the sections of the thermoelectric generator to be connected to each other by wire. This also minimizes the number of contacting and connecting points.

In one embodiment, the first side of the structural element, at least in some regions, has a coating and/or surface topography that promotes thermal absorption and/or heat absorption. This assures that the first side absorbs as much thermal energy as possible, which the thermoelectric generator can then convert into electrical energy. A coating that promotes thermal absorption can be produced, for example, by means of a black or dark coloring, in particular a black anodizing. A surface topography can also increase the surface area available for thermal absorption. Alternatively or in addition, anti-reflective layers can be applied to the surface.

In one embodiment, the second side of the structural element, at least in some regions, has a coating and/or surface topography that promotes thermal radiation and/or heat dissipation. It is thus possible to minimize the temperature of the second side and thus to increase the energy recovery by means of the thermoelectric generator. A coating that promotes thermal radiation can be produced, for example, by means of a black or dark coloring, in particular a black anodizing. A surface topography can increase the surface area available for heat dissipation.

In another embodiment, the structural element has a connecting section from which the energy generated by the thermoelectric generator can be tapped. The connecting section can have at least one flat connecting electrode that can be provided for a connection to a connecting line at or near an edge surface of the structural element. The connecting line can, for example, be embodied as plug-connectable or detachably clampable so that the electrical connection can be easily disconnected for a removal of the structural element. Alternatively or in addition, the connection can also be produced by means of crimping, riveting, or welding. In one embodiment, simply installing the structural element, in particular mounting the structural element in place, connects an electrode of the thermoelectric generator to the electrical system, for example in that an electrode of the thermoelectric generator is connected in an electrically conductive fashion to the vehicle chassis, which can constitute a reference electrode or ground electrode. It is therefore only necessary to connect one additional electrode of the thermoelectric generator to the electrical system.

In one embodiment, the structural element has a compensating section that is able to compensate for a temperature-induced change in the expanse of the structural element so that no impermissibly powerful mechanical stresses are exerted on the connecting section and/or a fastening section for fastening the structural element. For this purpose, the compensating section can be provided with surface structures such as folds or creases so that in the event of a temperature-induced change in expanse, the compensating section can deform like a bellows, for example. The compensating section can also protect the thermoelectric generator from temperature-induced mechanical stresses. This is particularly advantageous when the thermoelectric generator is manufactured out of a brittle material.

In one embodiment, the thermoelectric generator is manufactured, at least in part, using the thick-film or thin-film technique. The thermoelectric sections and/or the electrically conductive connections and/or the electrically conductive connecting surfaces of the thermoelectric generator can be manufactured using the thick-film or thin-film technique. In particular, the electrically conductive connections and the electrically conductive connecting terminals can be applied to the entire surface of the structural element, for example to a layer belonging to the structural element. They can be applied, for example, by being printed, vapor deposited, or precipitated onto the surface or applied to it using some other method. At least in some regions, the layers of the structural element constitute electrical connecting electrodes. In one embodiment, the thermoelectric generator is mounted in an at least essentially flat state onto the structural element, which is then bent into its final shape.

In one embodiment, the thermoelectric generator is at least partially composed of polymer-electronic, thermoelectric sections. Alternatively or in addition, at least the connecting lines are composed of polymer-electric sections. An advantage to the use of polymer electronics lies not only in the high degree of freedom with regard to the shape of the elements to be manufactured, but also in the comparatively low thermal conductivity, which increases the efficiency of the thermoelectric generator. The thermoelectric materials, for example in particulate form, can be incorporated into a polymer, which is then applied to the structural element, for example printed onto its surface.

In one embodiment, the thermoelectric generator can also be operated as a heat pump by connecting it to an electrical energy source. As a result, engine parts within the sphere of action of the structural element can be tempered, for example preheated from the cold state or kept at a constant temperature, which can increase the engine efficiency and/or the purification of exhaust gases.

Other advantages, features, and details of the invention ensue from the description below in which a number of exemplary embodiments are described in detail in conjunction with the drawings. The features mentioned in the description can each be essential to the invention individually or in any combination with one another.

### BRIEF DESCRIPTION OF THE DRAWINGS

FIG. 1 shows a section through a first exemplary embodiment of a structural element according to the invention.

FIG. 2 shows a section through a second exemplary embodiment of a structural element according to the invention.

### DETAILED DESCRIPTION OF THE PREFERRED EMBODIMENTS

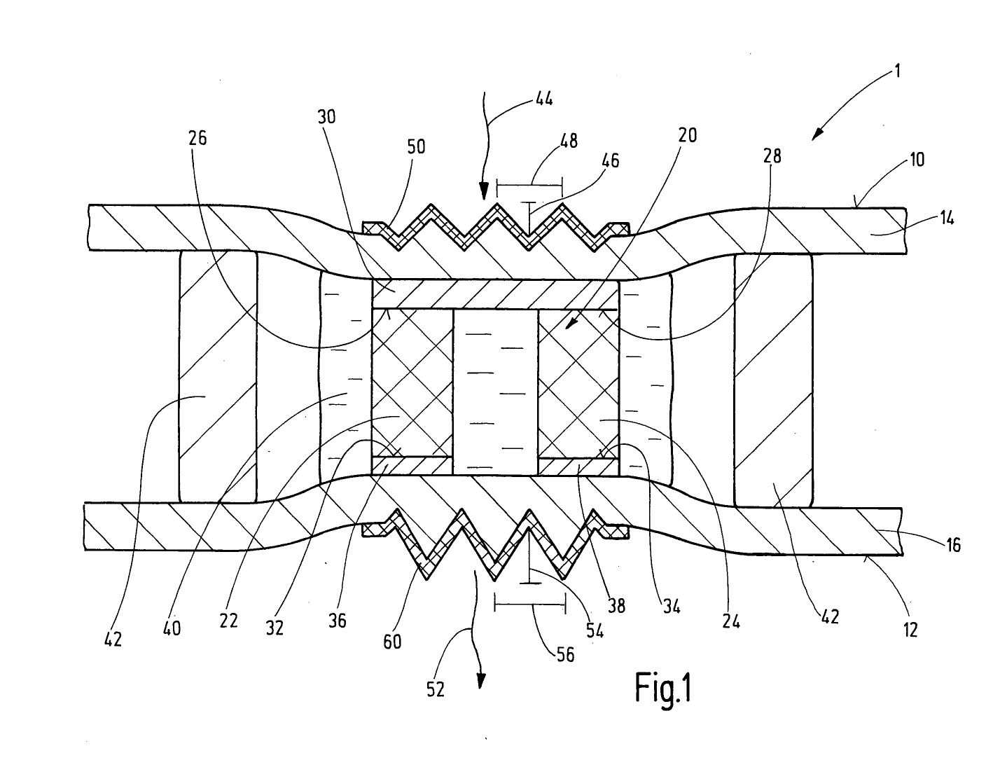

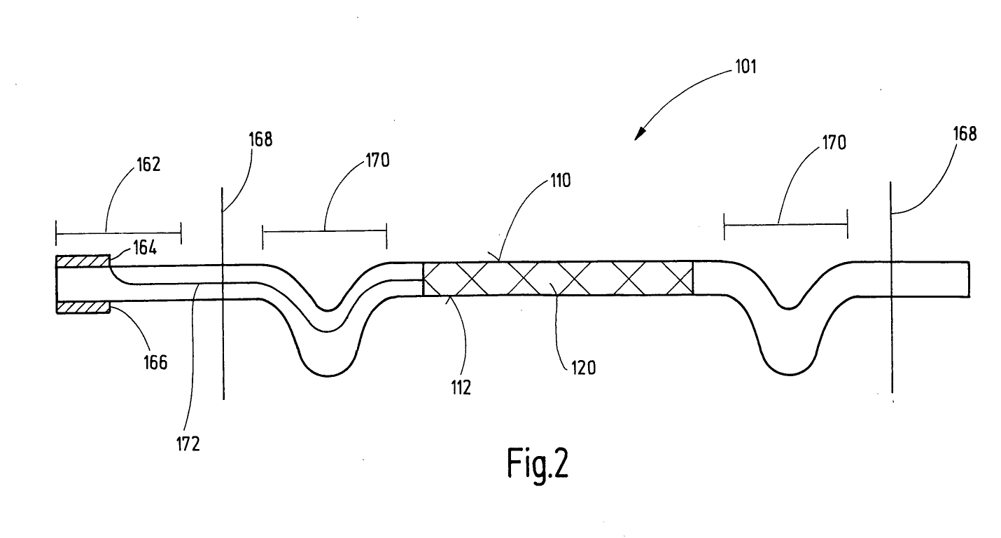

FIG. 1 shows a section through a first exemplary embodiment of a structural element 1 according to the invention for thermally shielding engines or engine components, embodied as a heat shield for combustion engines in the exemplary embodiment. The structural element 1 has a flat expanse and in particular also extends perpendicular to the plane of the drawing in FIG. 1. The structural element 1 has a first side 10 that is oriented toward a hot component of the engine, not shown, and a second side 12 that is oriented away from the hot engine component. The first side 10 in this case is composed of a first layer 14 and the second side 12 is composed of a second layer 16; the two layers 14, 16 are composed of sheet metal, for example sheet aluminum, with a thickness between 0.05 and 2 mm, in particular between 0.1 and 0.3 mm or between 0.3 and 0.8 mm. The depictions in FIGS. 1 and 2 are not to scale; in particular, the expanse of the thermoelectric generator 20 relative to the layers 14, 16 is not to scale.

Between the two layers 14, 16, there is a thermoelectric generator 20 that has a first section 22 and a second section 24. The two sections 22, 24 are made of a semiconducting thermoelectric material, for example bismuth telluride (Bi₂Te₃) or lead telluride (PbTe), and the first section 22 is p-doped while the second section 24 is n-doped. The first section 22 has a first end 26 that is electrically connected via a connecting bridge 30 to a first end 28 of the second section 24. In the simplest case, the connection can be produced by force-loaded contact of the two sections 22, 24 against the connecting bridge 30. The connecting bridge 30 can be applied to the first layer 14 using the thick-film or thin-film technique, either in a structured fashion, for example by means of screen printing, or over the entire surface with subsequent structuring. The two sections 22, 24 can also be applied using the thick-film or thin-film technique. The first ends 26, 28 of the first section 22 and second section 24 are thus connected to the first layer 14 in a thermally conductive fashion.

The first section 22 has a second end 32 that is connected to the second layer 16 in a thermally conductive fashion. The second end 32 is also electrically connected to the first connecting electrode 36, which can be applied to the second layer 16 using the thick-film or thin-film technique, either in a structured fashion, for example by means of screen printing, or over the entire surface with subsequent structuring. In a corresponding fashion, the second end 34 of the second section 24 is connected to a second connecting electrode 38. An electrical connection to other sections of the thermoelectric generator 20 and/or to an electrical system of the vehicle can be produced via the two connecting electrodes 36, 38, which in the exemplary embodiment extend perpendicular to the plane of the drawing in FIG. 1. In particular, the two connecting electrodes 36, 38 can preferably constitute integral connecting lines that lead to an edge of the structural element 1 and to a connecting region 162 situated there (FIG. 2).

The region between the sections 22, 24 of the thermoelectric generator 20 is filled with insulation material 40 that has a low thermal conductivity and has electrical insulating properties, e.g. glass, foam, or silicone. The insulation material 40 here fully encompasses the two sections 22, 24 and also adjoins the opposing layers 14, 16 and connecting bridge 30 as well as the connecting electrodes 36, 38. This reliably prevents the penetration of contaminants, in particular moisture.

The two layers 14, 16 overlap the thermoelectric generator 20 in the lateral direction, but also remain thermally insulated from each other in a region adjacent to the thermoelectric generator 20. For this purpose, the two layers 14, 16 are spaced apart from each other by a thermal insulation material 42 in a region adjacent to the thermoelectric generator 20. Basically, the thermal insulation material 42 can be made of the same material as the insulation material 40 in the region of the sections 22, 24 of the thermoelectric generator 20 and can even be of one piece with it. In the exemplary embodiment shown, the thermal insulation material 42, however, is spaced apart from the insulation material 40 and also serves as a spacer. The thermal insulation material 42 can in particular absorb compressive forces acting on the two layers 14, 16 and prevent them from acting on the thermoelectric generator 20. The thermal insulation material 42 can be made, for example, of glass, ceramic, or foam. It is also possible to use highly porous ceramics that have a high mechanical strength with a comparatively low thermal conductivity.

The first layer 14 has a surface topography that promotes the absorption of thermal radiation and/or thermal convection 44. In the exemplary embodiment shown, this is achieved by embossing the surface of the first side 10; the embossing depth 46 is between 25 and 200% of the distance 48 between two adjacent maxima, preferably between 50 and 100%. Alternatively or in addition, at least some regions of the first side 10 in the vicinity of the thermoelectric generator 20 are provided with a coating 50 that promotes thermal absorption, for example a dark or black anodizing of the first layer 14 made of aluminum.

In a corresponding fashion, the second layer 16, in the vicinity of the thermoelectric generator 20, has a surface topography that promotes heat dissipation 52, which in the exemplary embodiment is achieved by embossing the second layer 16. The embossing depth 54 is between 25 and 200% of the distance 56 between two adjacent maxima, preferably between 50 and 100%. The embossing depth 54 of the second layer 16 in this case can be 10 to 100% greater, preferably 20 to 80% greater than the embossing depth 46 of the first layer 14 in order to produce a sufficient heat dissipation 52 despite a low temperature gradient on the cold second side 12. Alternatively or in addition, at least some regions of the second side 12 in the vicinity of the thermoelectric generator 20 are provided with a coating 60 that promotes heat dissipation 52, which is embodied in the form of a dark or black anodizing of the second layer made of aluminum in the exemplary embodiment.

FIG. 2 shows a section through the second exemplary embodiment of a structural element 101 according to the invention. Spaced apart from the thermoelectric generator 120 in the lateral direction, in particular at the edge, the structural element 101 has a connecting section 162 from which the electrical energy generated by the thermoelectric generator 120 can be tapped. For this purpose, flat connecting electrodes 164, 166 are provided in the vicinity of the connecting section 162, a first connecting electrode 164 being provided on the first side 110 and a second connecting electrode 166 being provided on the second side 112 in the exemplary embodiment shown. The connecting electrodes 164, 166 can be connected to an additional connecting line, for example a connecting line leading to the electrical system of the vehicle. A connecting line 172 extending between the first side 110 and the second side 112 connects the first connecting electrode 164 to the thermoelectric generator 120. The second connecting electrode 166 is connected to the thermoelectric generator 120 via a metallic layer of the structural element 101 that constitutes the second side 112.

By means of fastening elements 168 that are only schematically depicted, the structural element 101 can be fastened, preferably in a detachable way, in the engine compartment of a motor vehicle, for example. For example, the fastening elements 168 can be composed of clamps or rivets that permit the structural element 101 to be detachably fastened.

On at least one side of the thermoelectric generator 120—on both sides of it in the exemplary embodiment—the structural element 101 has a compensating section 170 that is situated laterally between the thermoelectric generator 120 and the fastening element 168. If thermal irradiation causes an expansion in the lateral direction of the structural element 110, particularly in the region of the thermoelectric generator 120, then this expansion can be absorbed by the compensating sections 170, which are embodied in the form of creases in the exemplary embodiment, without the occurrence of impermissibly powerful mechanical stresses in the region of the thermoelectric generator 120.

If necessary, it is also possible to provide another compensating section between the fastening element 168 and the connecting section 162.

1. A structural element for thermally shielding engines or engine components, in particular a heat shield for combustion engines, the structural element comprising:
a flat expanse, with a first side that faces a hot component of an engine and a second side that faces away from the hot engine component; and
a thermoelectric generator that is able to generate electric energy from a temperature difference that arises between the first side and the second side of the structural element during operation of the engine.

2. The structural element as recited in claim 1, wherein the thermoelectric generator has a first section and a second section that each have a first end and a second end;
the two sections are composed of different materials or combinations of materials and/or are differently doped;
the first ends of the two sections are electrically connected to each other and are connected in a thermally conductive fashion to one of the two sides of the structural element; and
the second ends of the two sections are connected in a thermally conductive fashion to the other of the two sides of the structural element.

3. The structural element as recited in claim 1, wherein the thermoelectric generator has first and second sections that are spaced apart from each other and the a region between the sections is at least partially filled with a thermal insulation material.

4. The structural element as recited in claim 1, wherein the structural element is multilayered, having a first layer constituting the first side and a second layer constituting the second side, and the thermoelectric generator is situated between the two layers and is connected to the two layers in a thermally conductive fashion.

5. The structural element as recited in claim 4, wherein the two layers of the structural element overlap the thermoelectric generator and in a region adjacent to the thermoelectric generator, the two layers are spaced apart from each other by a thermal insulation material in a region adjacent the thermoelectric generator.

6. The structural element as recited in claim 4, wherein electrical connecting lines of the thermoelectric generator are at least partially routed between the two layers of the structural element.

7. The structural element as recited in claim 4, wherein at least one of the two layers of the structural element, on its side oriented toward the thermoelectric generator, has connecting electrodes for electrically contacting the thermoelectric generator and/or has electric conductor tracks.

8. The structural element as recited in claim 1, wherein the first side of the structural element comprising a first layer of a multipart structural element, at least in some regions, has a coating and/or surface topography that promotes thermal absorption and/or heat absorption.

9. The structural element as recited in claim 1, wherein the second side of the structural element comprising a second layer of a multipart structural element, at least in some regions, has a coating and/or surface topography that promotes thermal radiation and/or heat dissipation.

10. The structural element as recited in claim 1, wherein the structural element has a connecting section from which it is possible to tap energy generated by the thermoelectric generator.

11. The structural element as recited in claim 1, wherein the structural element has a compensating section that is able to compensate for a temperature-induced change in the expanse of the structural element so that no impermissible mechanical stresses are exerted on a fastening section for fastening the structural element and/or on a connecting section from which it is possible to tap the energy generated by the thermoelectric generator.

12. The structural element as recited in claim 1, wherein the thermoelectric generator is manufactured, at least in part, using a thick-film or thin-film technique applied to an entire surface of the structural element.

13. The structural element as recited in claim 1, wherein the thermoelectric generator is at least partially composed of polymer-electronic, thermoelectric sections.

14. The structural element as recited in claim 1, wherein it is also possible to operate the thermoelectric generator as a heat pump by connecting the thermoelectric generator to an electrical energy source.
